(19) United States
(12) Patent Application Publication
(10) Pub. No.: US 2023/0353118 A1
(43) Pub. Date: Nov. 2, 2023

(54) FILM BULK ACOUSTIC RESONATOR AND FABRICATION METHOD THEREOF

(71) Applicant: Ningbo Semiconductor International Corporation (Shanghai Branch), Shanghai (CN)

(72) Inventors: Herb He HUANG, Ningbo (CN); Hailong LUO, Ningbo (CN); Wei LI, Ningbo (CN)

(21) Appl. No.: 17/928,201

(22) PCT Filed: Dec. 11, 2020
(86) PCT No.: PCT/CN2020/135646

§ 371 Date: Nov. 28, 2022

(30) Foreign Application Priority Data
May 20, 2020 (CN) 202010431226.2

(51) Int. Cl. H03H 9/02; H03H 3/02; H03H 9/17

(52) U.S. Cl. CPC H03H 9/02015; H03H 3/02; H03H 9/173

(57) ABSTRACT

A film bulk acoustic resonator and fabrication method are provided. The film bulk acoustic resonator includes a carrier substrate, a support layer bonded to the carrier substrate and enclosing a cavity exposing a portion of the carrier substrate, a piezoelectric stacked-layer structure located above the support layer to cover the cavity and including a first electrode, a piezoelectric layer, and a second electrode stacked in sequence from bottom to top, and first and second bumps disposed at a boundary of an effective resonance region where the first electrode, the piezoelectric layer, and the second electrode above the cavity overlap each other in a direction perpendicular to a surface of the piezoelectric layer. The first and second bumps are disposed at sides of the first and second electrodes, respectively. At least one of projections of the first and second bumps on a plane where the piezoelectric layer is located includes a ring shape that includes an unclosed or closed ring.

### TECHNICAL FIELD

The present disclosure relates to the field of semiconductor device manufacturing and, more specifically, to a film bulk acoustic resonator and its fabrication method.

### BACKGROUND

With the continuous development of wireless communication technology, in order to meet the multi-functional requirements of various wireless communication terminals, the terminal equipment needs to be able to transmit data using different carrier frequency spectrums. At the same time, in order to support sufficient data transmission rate within a limited bandwidth, strict performance requirements are also put forward for the radio frequency system. A radio frequency (RF) filter is an important part of the RF system, which can filter out the interference and noise outside the communication spectrum to meet the signal-to-noise ratio requirements of the RF system and communication protocol. Take a mobile phone as an example, since each frequency band needs a corresponding filter, dozens of filters may need to be set in a mobile phone.

The film bulk acoustic resonator (FBAR) includes two film electrodes, and a piezoelectric film layer is arranged between the two film electrodes. The FBAR working principle is described as the following. The piezoelectric film layer is used to generate vibration under an alternating electric field; the vibration excites the bulk acoustic wave propagating along the thickness direction of the piezoelectric film layer; such acoustic wave may be reflected back from the interface between the air and each of the two film electrodes, and then be reflected back and forth inside the film layer to form an oscillation. When the acoustic wave propagates in the piezoelectric film layer having exactly an odd multiple of the half wavelength, a standing wave oscillation is formed.

However, the currently fabricated cavity-type film bulk acoustic resonators have shear wave loss and insufficient structural strength. As a result, the quality (Q) factor cannot be further improved and the yield it low to meet the requirements of high-performance RF systems.

### SUMMARY

In accordance with the disclosure, there is provided a film bulk acoustic resonator including a carrier substrate, a support layer bonded to the carrier substrate and enclosing a cavity exposing a portion of the carrier substrate, and a piezoelectric stacked-layer structure located above the support layer to cover the cavity and including a first electrode, a piezoelectric layer, and a second electrode stacked in sequence from bottom to top. A region where the first electrode, the piezoelectric layer, and the second electrode above the cavity overlap each other in a direction perpendicular to a surface of the piezoelectric layer constitutes an effective resonance region of the resonator. The resonator further includes a first bump and a second bump disposed at a boundary of the effective resonance region. The first bump is disposed at a side where the first electrode is located. The second bump is disposed at a side where the second electrode is located. At least one of a projection of the first bump or a projection of the second bump on a plane where the piezoelectric layer is located includes a ring shape that includes an unclosed ring or a closed ring.

Also in accordance with the disclosure, there is provided a film bulk acoustic resonator fabrication method including providing a temporary substrate, and forming a piezoelectric stacked-layer structure and a first bump on the temporary substrate. The piezoelectric stacked-layer structure includes a second electrode, a piezoelectric layer, and a first electrode sequentially formed on the temporary substrate. The first bump is disposed at a side where the first electrode is located. The method further includes forming a support layer to cover the piezoelectric stacked-layer structure, patterning the support layer to form a cavity penetrating the support layer, bonding a carrier substrate on the support layer covering the cavity, removing the temporary substrate, and forming a second bump on the second electrode. The first bump is located in an area enclosed by the cavity. At least one of a projection of the first bump or a projection of the second bump on a plane where the piezoelectric layer is located includes a ring shape that includes an unclosed ring or a closed ring.

The beneficial effect of the present disclosure is as follows.

At the boundary of the effective resonance region, the upper and lower surfaces can be respectively provided with a first bump and a second bump. The region where the first bump or the second bump is located can mismatch the acoustic impedance inside the effective resonance region. The projection of at least one of the first bump or the projection of the second bump on the plane where the piezoelectric layer is located can include a ring shape, and another bump can be arranged on one side. The acoustic impedance mismatch effect of the two bumps can be superimposed, and the structural balance can be improved, which effectively prevents the transverse leakage of the acoustic wave and further improves the quality factor of the resonator. Moreover, when the projections of the first bump and the second bump in the direction perpendicular to the piezoelectric layer overlap each other, the degree of acoustic impedance mismatch between the effective resonance region and the region where the bumps are located can be increased. When the projections of the first bump and the second bump in the direction of the piezoelectric layer are provided with overlapping parts in the radial direction from the center to the edge of the effective resonance region (that is, the projection of one bump is located outside the projection of the other bump), it is equivalent to setting two acoustic impedance mismatch regions.

Further, the effective resonance region of the resonator can be defined by the first trench and the second trench. The first trench and the second trench can penetrate the through the first electrode and the second electrode respectively, and the piezoelectric layer can keep a complete film layer without etching, which ensures the structural strength of the resonator and improves the yield of the resonator.

The fabrication method of the resonator of the present disclosure is a double-sided fabrication process, and the first bump can be formed on one side of the piezoelectric stacked-layer structure before bonding the carrier substrate. After removing the temporary substrate, the second bump can be formed on the other side of the piezoelectric stacked-layer structure. The conventional fabrication process is a single-sided fabrication process, and the bumps can only be formed on one side of the piezoelectric stacked-layer structure.

### BRIEF DESCRIPTION OF THE DRAWINGS

The above and other objects, features, and advantages of the present disclosure will become more apparent from the more detailed description of the exemplary embodiments of the present disclosure in conjunction with the accompanying drawings, in which the same reference numerals generally refer to the same parts.

FIG. 1 and FIG. 2 are schematic diagrams of a film bulk acoustic resonator according to an embodiment of the present disclosure.

FIG. 3 to FIG. 10 are schematic structural diagrams corresponding to various stages of a fabrication method of a film bulk acoustic resonator according to another embodiment of the present disclosure.

FIG. 11 to FIG. 18 are schematic structural diagrams corresponding to various stages of a fabrication method of a film bulk acoustic resonator according to another embodiment of the present disclosure.

### REFERENCE NUMERALS

100 Carrier substrate
101 Bonding layer
102 Support layer
103 First electrode
104 Piezoelectric layer
105 Second electrode
106 Joining layer
110a First cavity
110b Second cavity
120 Conductive interconnect structure
130a First trench
130b Second trench
1010 Frequency adjustment layer
140 First via
141 First conductive interconnect layer
142 First conductive bump
150 Second via
151 Second conductive interconnect layer
152 Second conductive bump
160 Insulation layer
200 Cap substrate
40a First bump
40b Second bump
300 Temporary substrate

### DETAILED DESCRIPTION OF THE EMBODIMENTS

The present disclosure will be further described in detail below with reference to the accompanying drawings and specific embodiments. The advantages and features of the present disclosure will become more apparent from the following description and accompanying drawings. However, it should be noted that the concept of the technical solution of the present disclosure can be implemented in many different forms and is not limited to the specific embodiments set forth herein. The accompanying drawings are all in a very simplified form and use inaccurate scales, and are only used to facilitate and clearly assist the purpose of explaining the embodiments of the present disclosure.

It should be understood that when an element or layer is referred to as being “on,” “neighboring,” “connected to,” or “coupled with” other elements or layers, the element can be directly on, directly neighboring, directly connected to or directly coupled with other elements or layers, or an intervening element may also be present between the element and other elements or layers. In contrast, when the element is referred to as being “directly on,” “directly neighboring,” “directly connected to,” or “directly coupled with” other elements or layers, no intervening element may be present between the element and the other elements or layers. It should be understood that although the terms “first,” “second,” “third,” etc. may be used to describe various elements, components, regions, layers and/or sections, these elements, components, regions, layers and/or sections should not be limited by these terms. These terms may only be used to distinguish one element, component, region, layer or section from another element, component, region, layer or section. Therefore, a first element, component, region, layer or section discussed below could be termed a second element, component, region, layer or section without departing from the teachings of the present disclosure.

Spatially relative terms, such as “beneath,” “below,” “lower,” “above,” “upper,” and the like, may be used herein for ease of description to describe one element or feature's spatial relationship to another element(s) or feature(s) as illustrated in the figures. It will be understood that the spatially relative terms may encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientation), and the spatially relative descriptors used herein shall be interpreted accordingly.

The terminology used herein is for the purpose of describing particular embodiments and is not intended to limit the inventive concept. As used herein, singular forms, “a,” “an,” and “the” may indicate plural forms as well, unless the context clearly indicates otherwise. The terms “includes” and/or “including,” when used in this specification, may specify the presence of stated features, integers, steps, operations, elements, and/or components, but may not preclude the presence or addition of one or more other features, integers, steps, operations, elements, components, and/or groups.

If any method described herein includes a sequence of steps, then the order of the steps presented herein does not have to be the only order in which the steps may be performed, and some of the steps may be omitted and/or some other steps not described herein may be added to the method. If any element in an embodiment of the present invention depicted in one of the accompanying drawings is identical to that in another one or other ones of the drawings, for the sake of clarity, a reference numeral for the element may not be marked in all of these figures even if the element is readily identifiable therein.

### Embodiment One

An embodiment of the present disclosure provides a film bulk acoustic resonator. FIG. 1 is a schematic diagram of the structure of a film piezoelectric acoustic resonator according to an embodiment of the present disclosure. Referring to FIG. 1, the film bulk acoustic resonator includes:
a carrier substrate 100;
a support layer 102 bonded to the carrier substrate 100, the support layer 102 enclosing a first cavity 110a, and the first cavity 110a exposing the carrier substrate 100; and
a piezoelectric stacked-layer structure located above the support layer 102 and covering the first cavity 110a, the piezoelectric stacked-layer structure including a first electrode 103, a piezoelectric layer 104, and a second electrode 105 stacked in sequence from bottom to top. A region where the first electrode 103, the piezoelectric layer 104, and the second electrode 105 located above the first cavity 110a overlapping each other in a direction perpendicular to the surface of the piezoelectric layer may constitute an effective resonance region of the resonator.

A first bump 40a and a second bump 40b are disposed at the boundary of the effective resonance region. The first bump 40a may be disposed at the side where the first electrode is located, and the second bump 40b may be disposed at the side where the second electrode is located. A projection of the first bump 40a and/or a projection of the second bump 40b on a plane where the piezoelectric layer 104 is located may include a ring shape, and the ring shape may be an unclosed ring or a closed ring. The shape of the ring may be a circle, an ellipse, a polygon, or an irregular shape composed of arcs and straight sides. The ring shape may be a closed ring or an unclosed ring. A closed ring means that the first bump 40a or the second bump 40b is continuous, and an unclosed ring means that the first bump 40a or the second bump 40b is discontinuous. At the boundary of the effective resonance region, the upper and lower surfaces may be respectively provided with a first bump and a second bump. A region where the first bump or the second bump is located may mismatch an acoustic impedance inside the effective resonance region. At least one of the projection of the first bump or the projection of the second bump on the plane where the piezoelectric layer is located may include a ring shape, and another bump may be arranged on one side. The acoustic impedance mismatch effect of the two bumps can be superimposed, and the structural balance can be improved, which effectively prevents the transverse leakage of the acoustic wave and further improves the quality factor of the resonator.

In this embodiment, the first bump 40a is located at the side where the first electrode 103 of the piezoelectric stacked-layer structure is located and is close to the carrier substrate 100; and the second bump 40b is located at the side where the second electrode 105 of the piezoelectric stacked-layer structure is located, away from the carrier substrate 100. The first bump 40a protrudes from the lower surface of the piezoelectric stacked-layer structure, that is, the top surface of the first bump 40a is lower than the lower surface of the first electrode 103. The second bump 40b protrudes from the upper surface of the piezoelectric stacked-layer structure, that is, the top surface of the second bump 40b is higher than the upper surface of the second electrode 105. The projections of the first bump 40a and the second bump 40b on the carrier substrate 100 each enclose a closed ring shape, such as a closed irregular polygon, circle or ellipse. The overlapping region surrounded by the first bump 40a and the second bump 40b is the effective resonance region. The first electrode 103, the piezoelectric layer 104, and the second electrode 105 in the effective resonance region overlap each other in the direction perpendicular to the carrier substrate 100.

In this embodiment, the first bump 40a and the second bump 40b overlap in the direction perpendicular to the piezoelectric layer 104. The overlap may include at least the following three situations. In the first situation, the projection shapes of the first bump 40a and the second bump 40b are the same, and they completely overlap. In the second situation, the projection area of one of the first bump 40a and the second bump 40b is larger than the projection area of the other bump, and the projection with the larger area cover the projection of the smaller area. In the third situation, the two projections partially overlap, for example, the shape of the two projections may be substantially the same, the overlapping parts of the two projections may be continuous, or one of the projections may only have a portion that overlaps with the other projection. Compared with forming bumps on only one surface of the piezoelectric stacked-layer structure, this arrangement can improve the degree of impedance mismatch, effectively prevent the leakage of transverse waves, and improve the quality factor of the resonator. In other embodiments, the first bump 40a and the second bump 40b may partially overlap in the direction perpendicular to the piezoelectric layer 104 or, overlapping parts of the projections of the first bump 40a and the second bump 40b in the direction of the piezoelectric layer may be disposed along the radial direction from the center to the edge of the effective resonance region (that is, the projection of one of the bumps may be located outside the other projection, for example, the projection of the first bump may be in a ring shape, and the projection of the second bump may surround the projection of the first projection). In this case, when the transverse acoustic wave is transmitted to the area where the first bump is located, a sound wave reflection can be generated, and when the remaining transverse acoustic wave continues to transmit to the area where the second bump is located, another sound wave reflection can be generated. Through two reflections, the leakage of transverse acoustic waves can be effectively prevented, and the quality factor of the resonator can be improved.

In this embodiment, the first bump 40a and the second bump 40b can make the internal effective resonance region surrounded by the acoustic impedance mismatch the area where the first bump 40a and the second bump 40b are located, which can effectively prevent the transverse leakage of acoustic waves and improve the quality factor of the resonator. In other embodiments, the respective projections of the first bump 40a and the second bump 40b on the carrier substrate 100 may not be completed closed shapes. It should be understood that when the projections of the first bump 40a and the second bump 40b on the carrier substrate 100 are closed shapes, it is more beneficial to prevent the transverse leakage of acoustic waves.

The material of the first bump 40a and the second bump 40b may be a conductive material or a dielectric material. When the material of the first bump 40a is a conductive material, it can be the same material of the first electrode 103. In some embodiments, the first electrode 103 may include the first bump 40a, and the first bump 40a and the first electrode 103 may be integrally formed. When the material of the second bump 40b is a conductive material, it can be the same material of the second electrode 105. In some embodiments, the second electrode 105 may include the second bump 40b, and the second bump 40b and the second electrode 105 may be integrally formed. When the materials of the first bump 40a and the second bump 40b are dielectric materials, they may be any one of silicon oxide, silicon nitride, silicon oxynitride or silicon carbonitride, but are not limited to the above materials.

The carrier substrate 100 may include at least one of the following materials of silicon (Si), germanium (Ge), silicon germanium (SiGe), silicon carbide (SiC), silicon germanium carbide (SiGeC), indium arsenide (InAs), gallium arsenide (GaAs), indium phosphide (InP), or other III/V compound semiconductors, and may also include a multiplayer structure composed of these semiconductors, and may also be a ceramic substrate such as alumina, a quartz or glass substrate, etc.

The support layer 102 may be bonded to the carrier substrate 100. The support layer 102 may enclose the first cavity 110a, the first cavity 110a may expose the carrier substrate 100. In one embodiment, the first cavity 110a may be a ring-shaped closed cavity, and the first cavity 110a may be formed by etching the support layer 102 through an etching process, but the technology of the present disclosure is not limited thereto. It should be noted that the support layer 102 can be combined with the carrier substrate 100 by bonding, and the bonding methods may include covalent bonding, adhesive bonding or fusion bonding. In other embodiments, the support layer 102 and the carrier substrate 100 may be bonded through a bonding layer, and the material of the boding layer may include silicon oxide, silicon nitride, silicon oxynitride, silicon carbonitride or ethyl silicate.

In this embodiment, the shape of the bottom surface of the first cavity 110a may be a rectangle, but in other embodiments of the present disclosure, the shape of the bottom surface of the first cavity 110a on the bottom surface of the first electrode 103 may also be a circle, an ellipse, or a polygon other than a rectangle, such as a pentagon, a hexagon, etc. The material of the support layer 102 may be any suitable dielectric material, including but not limited to one of silicon oxide, silicon nitride, silicon oxynitride, silicon carbonitride or other materials. In other embodiments, the materials of the support layer 102 and the bonding layer may be the same.

A piezoelectric stacked-layer structure may be disposed above the first cavity 110a, and the piezoelectric stacked-layer structure may include a first electrode 103, a piezoelectric layer 104, and a second electrode 105 in sequence from bottom to top. The first electrode 103 may be disposed at the support layer 102, the piezoelectric layer 104 may be disposed at the first electrode 103, and the second electrode 105 may be disposed at the piezoelectric layer 104. An overlapping region in the direction perpendicular to the carrier substrate 100 may be arranged on the first electrode 103, the piezoelectric layer 104 and the second electrode 105 above the first cavity 110a. The overlapping region of the region surrounded by the first bump 40a and the second bump 40b can be an effective resonance region.

In one embodiment, the piezoelectric layer 104 may cover the first cavity 110a. The piezoelectric layer 104 covering the first cavity 110a should be understood as the piezoelectric layer 104 being a complete layer without being etched. It does not necessarily mean the piezoelectric layer 104 completely covering the first cavity 110a to form a sealed cavity. Of course, in some embodiments, the piezoelectric layer 104 may completely cover the first cavity 110a to form a sealed cavity. Not etching the piezoelectric layer can ensure that the piezoelectric layer have a certain thickness, such that the resonator can have a certain structural strength, thereby improving the yield of manufacturing the resonators.

In one embodiment, an etch stop layer may be further disposed between the support layer 102 and the first electrode 103, and its material may include, but is not limited to, silicon nitride (Si₃N₄) and silicon oxynitride (SiON). On the one hand, the etch stop layer can be used to increase the structural stability of the final fabricated film bulk acoustic resonator. On the other hand, compared with the support layer 102, the etch stop layer has a lower etching rate, which can prevent over-etching during the process of etching the support layer 102 to form the first cavity 110a, and protect the surface of the first electrode 103 under it from being damage, thereby improving the device performance and reliability.

In one embodiment, the surface of the piezoelectric stacked-layer structure may further include a first trench 130a and a second trench 130b. The first trench 130a may be disposed in the lower surface of the piezoelectric stacked-layer structure, at the side where the first cavity 110a is located, running through the first electrode 103, and surrounding the outer periphery of the area where the first bump 40a is located. The second trench 130b may be disposed in the upper surface of the piezoelectric stacked-layer structure, running through the first electrode 103, and surrounding the outer periphery of the area where the second bump 40b is located. The two ends of the first trench 130a and the two ends of the second trench 130b may be disposed opposite to each other, such that the projections of the first trench 130a and the second trench 130b on the carrier substrate 100 can meet or have a gap at the two junctions. In one embodiment, the projections of the first bump 40a and the second bump 40b on the piezoelectric layer 104 may be closed polygons. The inner edges of the first trench 130a and the second trench 130b may be respectively disposed along the outer boundaries of the first bump 40a and the second bump 40b, that is, the outer boundaries of the first bump 40a and the second bump 40b may coincide with the inner edges of the first trench 130a and the second trench 130b, respectively. The projections of first trench 130a and the second trench 130b on the carrier substrate 100 may be closed shaped, which may be respectively consistent with the projected shapes of the first bump 40a and the second bump 40b on the carrier substrate 100, and may be located at the outer periphery of the projections formed by the first bump 40a and the second bump 40b, respectively.

The first bump 40a and the second bump 40b can cause the acoustic impedance of the region inside the bump to mismatch the acoustic impedance of the region where the bump is located, which defines the boundary of the effective resonance region of the resonator. The first trench 130a and the second trench 130b can separate the first electrode 103 and the second electrode 105, respectively, such that the resonator cannot meet the working condition (the working condition is that the first electrode 103, the piezoelectric layer 104, and the second electrode 105 overlap each other in the thickness direction), which further defines the boundary of the effective resonance region of the resonator. The first bump 40a and the second bump 40b can cause the acoustic impedance mismatch through the addition of mass, and the first trench 130a and the second trench 130b can cause the acoustic impedance mismatch by causing the electrode end face to contact with air. Both effects can prevent the leakage of the transverse wave and improve the Q value of the resonator. Of course, in other embodiments, only the first trench 130a or the second trench 130b may be provided. Since electrical signals need to be introduced to the first electrode 103 and the second electrode 105, the first trench 130a or the second trench 130b is not suitable to form a closed ring. Thus, the first trench 130a or the second trench 130b cannot completely surround the region where the first bump 40a or the second bump 40b is located. Therefore, the first trench 130a or the second trench 130b may be formed into a nearly closed ring, and the non-closed area may be used for introducing electrical signals. This arrangement can simplify the process flow and reduce the cost of the resonator.

In one embodiment, the film bulk acoustic resonator may further include a frequency adjustment layer disposed at the surface of the first electrode 103 in the effective resonance region. In another embodiment, the frequency adjustment layer may be disposed at the surface of the second electrode 105 in the effective resonance region. The frequency adjustment layer can be used to adjust the frequency of the resonator. The frequency of the resonator is related to the thickness of the effective resonance region. When a filter is being fabricated, the thickness of the first electrode 103, the second electrode 105, and the piezoelectric layer 104 of different resonators may be the same. In order to make the frequencies of different resonators different, frequency adjustment layers with different thicknesses can be arranged. In one embodiment, the material of the frequency adjustment layer may be ethyl silicate. The material of the frequency adjustment layer may also be silicon oxide, silicon nitride, silicon oxynitride, or silicon carbonitride.

In one embodiment, a joining layer 106 may be further included. The joining layer 106 may be disposed above the piezoelectric stacked-layer structure to enclose the second cavity 110b. The second cavity 110b may expose the upper surface of the piezoelectric stacked-layer structure. The second cavity 110b may be disposed above the first cavity 110a, and the first trench 130a and the second trench 130b may be disposed inside the area enclosed by the second cavity 110b. The film bulk acoustic resonator may further include a cap substrate 200 disposed at the joining layer 106 and covering the second cavity 110b. In one embodiment, the joining layer 106 may form a closed ring, and the second cavity 110b may be a closed cavity. A part of the lower surface of the joining layer 106 may be connected to the second electrode 105 outside the effective resonance region, and a part may be connected to the first electrode 103 outside the effective resonance region. The joining layer 106 may be made of bonding materials such as silicon oxide, silicon nitride, silicon oxynitride, ethyl silicate, etc., or may be adhesives such as photo-curable materials or thermal-curable materials, such as die attach film (DAF) or dry film. The material of the joining layer and the material of the cap substrate 200 may be the same, and the two may be an integral structure. The second cavity 110b may be formed by forming a space in the film layer (for forming the joining layer 106 and the cap substrate 200).

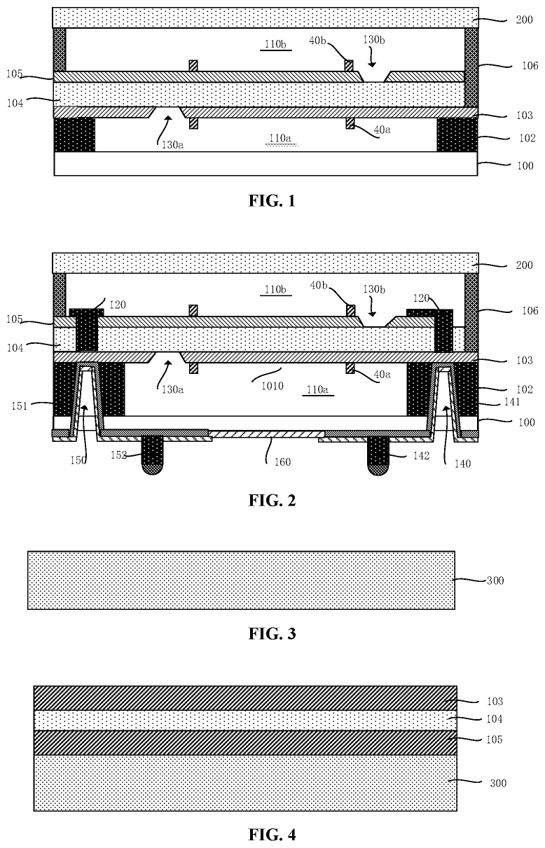

Referring to FIG. 2, in one embodiment, a first electrical connection, a second electrical connection, and a conductive interconnect structure 120 may also be included. The electrical connection may be used for introducing an electrical signal into the first electrode 103 of the effective resonance region, and the second electrical connection may be used for introducing an electrical signal into the second electrode 105 of the effective resonance region. After the first electrode 103 and the second electrode 105 are energized, a voltage different can be generated above and below the surface of the piezoelectric layer 104 to form a standing wave oscillation. The conductive interconnect structure 120 may be used to short the first electrode and the second electrode outside the effective resonance region. It can be seen from FIG. 2 that the area where the piezoelectric layer, the first electrode, and the second electrode overlap each other in the direction perpendicular to the piezoelectric layer is also included outside the effective resonance region. When the first electrode and the second electrode are energized, a voltage difference can also be generated above and below the surface of the piezoelectric layer outside the effective resonance region, and a standing wave oscillation can also be generated. However, standing wave oscillation outside the effective resonance region is undesirable. In this embodiment, the first electrode and the second electrode outside the effective resonance region can be short-circuited, such that the upper and lower voltages of the piezoelectric layer outside the effective resonance region can be consistent, and the standing wave oscillation cannot be generated outside the effective resonance region, which improves the Q value of the resonator. The specific structure of the first electrical connection, the second electrical connection, and the conductive interconnect structure 120 may be as follow.

The first electrical connection may include a first via 140, the first via 140 penetrating the lower structure of the first electrode 103 outside the effective resonance region to expose the first electrode 103; a first conductive interconnect layer 141 covering the inner surface of the first via 140 and a part of the surface of the carrier substrate 100 around the first via 140, and being connected to the first electrode 103; an insulation layer 160 covering the first conductive interconnect layer 141 and the surface of the carrier substrate 100; and a first conductive bump 142 disposed at the surface of the carrier substrate 100 and electrically connected to the first conductive interconnect layer 141.

The second electrical connection may include a second via 150, the second via 150 penetrating the lower structure of the first electrode 103 outside the effective resonance region to expose the first electrode 103; a second conductive interconnect layer 151 covering the inner surface of the second via 150 and a part of the surface of the carrier substrate 100 around the second via 150, and being connected to the first electrode 103; an insulation layer 160 covering the second conductive interconnect layer 151 and the surface of the carrier substrate 100; and a second conductive bump 152 disposed at the surface of the carrier substrate 100 and electrically connected to the second conductive interconnect layer 151.

In one embodiment, the conductive interconnect structure 120 may include two parts. One part may be disposed in the outer area of the second trench 130b, connecting the first electrode 103 and the second electrode 105, and electrically connected to the first electrical connection through the first electrode 103. The other part of the conductive interconnect structure 120 may be disposed in the outer area of the first trench 130a, connecting the first electrode 103 and the second electrode 105, and electrically connected to the second electrical connection through the first electrode 103. Both parts of the conductive interconnect structure 120 may be provided with an area covering part of the surface of the second electrode 105. These areas can increase the contact areas with the second electrode 105, reduce the contact resistance, and can prevent local high temperature caused by excessive current.

It should be noted that the second electrical connection may not be directly electrically connected to the second electrode, but may be connected to the first electrode outside the effective resonance region, and electrically connected to the second electrode of the effective resonance region through the conductive interconnect structure 120. It can be seen that the first electrical connection and the second electrical connection may be the same in structure, but may be arranged in different positions. The first electrical connection may be electrically connected to the first electrode inside the effective resonance region and supply power to the first electrode inside the effective resonance region. The first electrical connection may be electrically connected to the second electrode outside the effective resonance region through the first electrode outside the effective resonance region and the conductive interconnect structure 120, without being connected to the second electrode inside the effective resonance region. Similarly, the second electrical connection may be connected to the first electrode outside the effective resonance region and the second electrode inside the effective resonance region to supply power to the second electrode inside the effective resonance region.

### Embodiment Two

An embodiment of the present disclosure provides a film bulk acoustic resonator fabrication method. The method may include the following processes.
SO1: providing a temporary substrate;
SO2: forming a piezoelectric stacked-layer structure and a first bump on the temporary substrate, the piezoelectric stacked-layer structure including a second electrode, a piezoelectric layer, and a first electrode sequentially formed on the temporary substrate, the first bump being disposed at the side where the first electrode is located;
SO3: forming a support layer to cover the piezoelectric stacked-layer structure;
SO4: patterning the support layer to form a first cavity, the first cavity penetrating the support layer, and the first bump being disposed in the area enclosed by the first cavity;
SO5: bonding a carrier substrate on the support layer, the carrier substrate covering the first cavity;
SO6: removing the temporary substrate; and
SO7: forming a second bump on the second electrode, the projection of the first bump and/or the projection of the second bump on the plane where the piezoelectric layer is located including a ring shape, the ring shape including an unclosed ring or a closed ring.

FIGS. 3-10 are schematic structural diagrams of different stages of a film bulk acoustic resonator fabrication method according to an embodiment of the present disclosure. The method will be described in detail below. It should be noted that the step numbers (SON) do not represent a sequence.

Referring to FIG. 3. SO1: providing a temporary substrate 300.

The temporary substrate 300 may be at least one of the following materials of silicon (Si), germanium (Ge), silicon germanium (SiGe), silicon carbide (SiC), silicon germanium carbide (SiGeC), indium arsenide (InAs), gallium arsenide (GaAs), indium phosphide (InP), or other III/V compound semiconductors, and may also include a multiplayer structure composed of these semiconductors, and may also be a ceramic substrate such as alumina, a quartz, or glass substrate, etc.

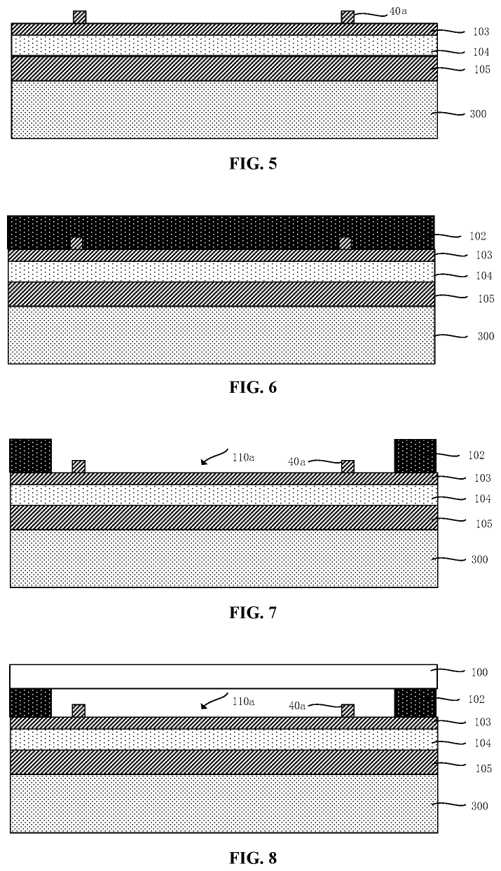

Referring to FIGS. 4 and 5. SO2: forming a piezoelectric stacked-layer structure and a first bump 40a on the temporary substrate 300, the piezoelectric stacked-layer structure including a second electrode 105, a piezoelectric layer 104, and a first electrode 103 sequentially formed on the temporary substrate 300, the first bump 40a being disposed at the side where the first electrode 103 is located.

The material of the second electrode 105 and the first electrode 103 may be any suitable conductive material or semiconductor material. In some embodiments, the conductive material may be a metal material with conductive properties, such as molybdenum (Mo), aluminum (Al), copper (Cu), tungsten (W), tantalum (Ta), platinum (Pt), ruthenium (Ru), rhodium (Rh), iridium (Ir), chromium (Cr), titanium (Ti), gold (Au), osmium (Os), rhenium (Re), and palladium (Pd), or a laminate of the above metals. The semiconductor material may be, for example, Si, Ge, SiGe, SiC, SiGeC, etc. The second electrode 105 and the first electrode 103 may be formed by physical vapor deposition such as magnetron sputtering, evaporation, or chemical vapor deposition. The piezoelectric layer 104 may be made of piezoelectric material having a wurtzite crystal structure, such as aluminum nitride (AlN), zinc oxide (ZnO), lead zirconate titanate (PZT), lithium niobate (LiNbO₃), quartz, potassium niobate (KNbO₃), or lithium tantalate (LiTaO₃), or a combination thereof. When the piezoelectric layer 104 includes aluminum nitride (AlN), the piezoelectric layer 104 may further include a rare earth metal such as at least one of scandium (Sc), erbium (Er), yttrium (Y), and lanthanum (La). In addition, when the piezoelectric layer 104 includes aluminum nitride (AlN), the piezoelectric layer 104 may further includes a transition metal such as at least one of zirconium (Zr), titanium (Ti), manganese (Mn), and hafnium (Hf). The piezoelectric layer 104 may be deposited using any suitable method know to those skilled in the art, such as chemical vapor deposition, physical vapor deposition, or atomic layer deposition. In some embodiments, the second electrode 105 and the first electrode 103 may be made of metal molybdenum (Mo), and the piezoelectric layer 104 may be made of aluminum nitride (AlN). There are various methods for forming the first bump, which will be elaborated in the subsequent description.

Referring to FIG. 6. SO3: forming a support layer 102 to cover the piezoelectric stacked-layer structure.

The support layer 102 may be formed by physical vapor deposition or chemical vapor deposition. The material of the support layer 102 may be any suitable dielectric material, including but not limited to at least one of silicon oxide, silicon nitride, silicon oxynitride, silicon carbonitride and other materials.

Referring to FIG. 7. SO4: patterning the support layer 102 to form a first cavity 110a, the first cavity 110a penetrating the support layer 102, and the first bump 40a being disposed in the area enclosed by the first cavity 110a.

The support layer 102 may be etched through an etching process to form a first cavity 110a to expose the first electrode 103 and the first bump 40a at the bottom. The etching process may be wet etching or dry etching, and dry etching may include, but is not limited to, reactive ion etching (RIE), ion beam etching, and plasma etching. The depth and shape of the first cavity 110a may be determined by the depth and shape of the cavity required for the film bulk acoustic resonator to be fabricated, that is, the depth of the first cavity 110a may be determined by forming the thickness of the support layer 102. The shape of the bottom surface of the first cavity 110a may be a rectangle or a polygon other than a rectangle, such as a pentagon, a hexagon, an octagon, etc., or a circle or an ellipse.

Referring to FIG. 8. SO5: bonding a carrier substrate 100 on the support layer 102, the carrier substrate 100 covering the first cavity 110a. For the material of the carrier substrate 100, reference can be made to the material of the temporary substrate 300. The bonding between the carrier substrate 100 and the support layer 102 may be realized by thermocompression bonding, or the bonding between the carrier substrate 100 and the support layer 102 may be realized by dry film bonding.

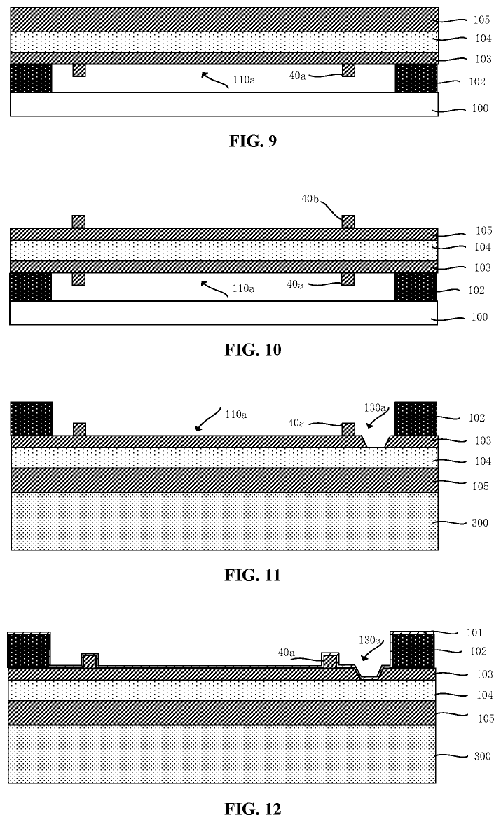

Referring to FIG. 9. SO6: removing the temporary substrate 300. The temporary substrate may be removed through mechanical grinding.

Referring to FIG. 10. SO7: forming a second bump 40b on the second electrode 105, the projection of the first bump 40a and/or the projection of the second bump 40b on the plane where the piezoelectric layer 104 is located including a ring shape, the ring shape including an unclosed ring or a closed ring.

For the structure, positional relationship and beneficial effects of the first bump 40a and the second bump 40b, reference can be made to the previous embodiments, which will not be repeated here.

In one embodiment, the method for forming the first bump 40a and the second bump 40b may be as follow. First, sequentially forming a second conductive material layer and the piezoelectric layer 104 on the temporary substrate 300. The thickness of the second conductive material layer may be the sum of the thickness of the second electrode 105 and the second bump 40b. Next, forming a first conductive material layer on the piezoelectric layer 104. The thickness of the first conductive material layer formed at this time may be the sum of the thickness of the first electrode 103 and the first bump 40a. After the first conductive material layer is formed, the first conductive material layer with a set thickness may be etched to form the first bump 40a and the first electrode 103. After the temporary substrate 300 is removed, the second conductive material with a set thickness may be etched to form the second bump 40b and the second electrode 105. There are various methods for forming the first bump 40a and the 40b in the present disclosure, and there are two methods to form the bumps based on the material of the bumps.

In the first method, a structural material layer is formed on the temporary substrate, the second electrode or the piezoelectric layer, and the first bump is formed by etching the structural material layer. The structural material layer formed on the temporary substrate may be used to form the second electrode, the structural material layer formed on the second electrode may be used to form the piezoelectric layer, and the structural material layer formed on the piezoelectric layer may be used to form the first electrode. In some embodiments, the first bump can be formed by using the method described above. Further, after forming the structural material layer on the temporary substrate and removing the temporary substrate, an etching process is performed on the structural material layer to form the second bump, and the structural material layer may be used to form the second electrode. In some embodiments, the first bump and the second bump can be formed by using the method described above.

In the second method, a bump material layer is formed on the temporary substrate, the second electrode, the piezoelectric layer or the first electrode 103, and an etching process is performed on the bump material layer to form the first bump. After removing the temporary substrate, a bump material layer is formed on the second electrode, and an etching process is performed on the bump material layer to form the second bump.

In the first method, the materials of the bump material layer and the structural material layer are the same, and the structural material layer and the bump material layer can be formed by one deposition process, thereby reducing the number of process steps. In the second method, the materials of the bump material layer and the structural material layer are the different and two deposition processes are needed. However, the selection of the bump material is not limited to be the same as the material of the first electrode, the second electrode or the piezoelectric layer, and the selection range of the bump material is wider.

For any of the above methods, a specific method for forming the piezoelectric stacked-layer structure, the first bump and the second bump may include the following methods.

In the first method, the second electrode, the piezoelectric layer, and the first electrode are sequentially formed on the temporary substrate, and the first bump is formed on the first electrode. After removing the temporary substrate, the second bump is formed on the second electrode. The material of the first bump and the material of the first electrode may be the same or different. Similarly, the material of the second bump and the material of the second electrode may be the same or different. In one embodiment, the materials of the two may be the same, the conductive material layer may be formed by a deposition process, the first electrode and the first bump may be formed by an etching process, and the second electrode and the second bump may be formed using a similar process. In other embodiments, the two materials may be different, and the second electrode and the first electrode may be formed first, then the second bump material layer and the first bump material layer may be formed by a deposition process, and then the first bump and the second bump may be formed by an etching process.

In the second method, the second electrode and the piezoelectric layer are sequentially formed on the temporary substrate. The first bump is formed on the piezoelectric layer, and the first electrode is formed on the first bump and the piezoelectric layer. After removing the temporary substrate, the second bump is formed on the second electrode. The difference between the second method and the first method is that the first bump of the first method is formed on the first electrode, and the first bump of the second method is formed on the piezoelectric layer. Forming the first bump in this way also includes two cases. In the first case, the material of the first bump may be the same as the material of the piezoelectric layer, and the first bump may be formed by one deposition process. A piezoelectric material layer may be formed on the second electrode, and the thickness of the piezoelectric material layer may be the sum of the heights of the first bump and the piezoelectric layer. Subsequently, the piezoelectric layer and the first bump may be formed by an etching process. In the second case, the first bump and the piezoelectric layer may be formed separately. First, a piezoelectric layer may be formed on the second electrode, then a first bump material layer may be formed on the piezoelectric layer. The first bump may be formed by an etching process, and the first electrode may be formed on the first bump and the piezoelectric layer.

Similarly, forming the second bump also includes two cases. In the first case, the material of the second bump may be the same as the material of the second electrode, and the second bump may be formed by one deposition process. At this time, a conductive material layer may be formed on the temporary substrate, and the thickness of the conductive material layer may be the sum of the heights of the second bump and the second electrode. After removing the temporary substrate, the second electrode and the second bump may be respectively formed through an etching process. In the second case, the second bump and the second electrode may be formed separately. First, the second electrode may be formed on the temporary substrate. After removing the temporary substrate, a second bump material layer may be formed on the second electrode, and the second bump may be formed through an etching process.

In the third method, the second electrode is formed on the temporary substrate, the first bump is formed on the second electrode, and the piezoelectric layer and the first electrode are sequentially formed on the first bump and the second electrode. After removing the temporary substrate, the second bump is formed on the second electrode. The difference between the third method and the second method is that the first bump in the second method is formed on the piezoelectric layer, and the first bump of the third method is formed on the second electrode. For the materials and forming methods of the second bump and the first bump, reference can be made to the second method described above, which will not be repeated here.

In the fourth method, the first bump is formed on the temporary substrate, and on the first bump, the second electrode, the piezoelectric layer, and the first electrode are sequentially formed on the temporary substrate. After the removing the temporary substrate, the second bump is formed on the second electrode. The material of the first bump in the fourth method may be the same as or different from that of the first electrode. For the forming method of the first bump, reference can be made to the second method described above. For the material and forming method of the second bump, reference can be made to the second method described above, which will not be repeated here.

### Embodiment Three

An embodiment of the present disclosure provides another film bulk acoustic resonator fabrication method. FIGS. 11-18 are schematic diagrams of corresponding structures in different steps of the fabrication method.

Referring to FIGS. 11-18, the processes of SO1 to SO4 in this embodiment are the same as those in the previous embodiment. The main difference from the previous embodiment is that after the process at SO4, and before the process at SO5, the method further includes forming the first trench 130a surrounding the first bump 40a at the bottom of the first cavity 110a and at the periphery of the first bump 40a, the first trench 130a penetrating the first electrode 103. After the process at SO7, the method further includes forming a second trench 130b on the second electrode 105 on the opposite side of the first trench 130a, the second trench 130b surrounding the second bump 40b, and the second trench 130b penetrating the second electrode 105; and projections of the first trench 130a and the second trench 130b on the carrier substrate 100 meeting or having a gap at the two junctions of the projections.

More specifically, referring to FIG. 11, the first electrode 103 may be etched to form the first trench 130a in the first cavity 110a and the outer periphery of the first bump 40a, and the sidewall of the first trench 130a may be inclined or vertical. In this embodiment, the sidewall of the first trench 130a forms an obtuse angle with the plane where the piezoelectric layer 104 is located (the longitudinal section (section along the thickness direction of the film) of the first trench 130a is a trapezoid). The projection of the first trench 130a on the plane where the piezoelectric layer 104 is located may be a half-ring or a polygon similar to a half-ring.

Referring to FIG. 12. In this embodiment, after forming the first trench 130a, the method further includes forming a bonding layer 101 on the surface of the support layer 102, the bonding layer 101 being used for bonding the support layer 102 and the carrier substrate 100. The bonding layer 101 may be formed on the surfaces of the support layer 102, the first electrode 103, the first bump 40a and the first trench 130a through a deposition process. The material of the bonding layer may include silicon oxide, silicon nitride, silicon oxynitride, silicon carbonitride or ethyl silicate. From the materials of the support layer 102 described above, the materials of the support layer 102 and the bonding layer 101 may be the same. In some embodiments, the material of the bonding layer 101 may be ethyl silicate.

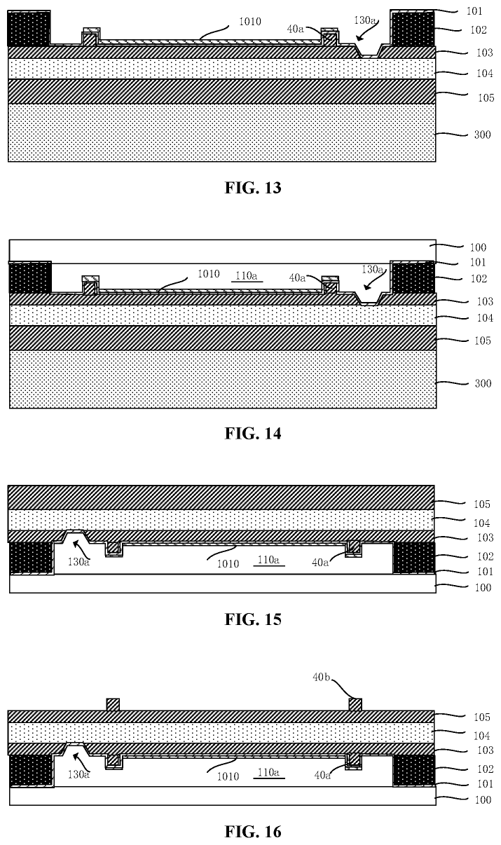

Referring to FIG. 13. In this embodiment, after forming the bonding layer 101, the method further includes forming a frequency adjustment layer 1010 on the surface of the first electrode 103 surrounded by the first bump 40a. It should be noted that forming the frequency adjustment layer 1010 and the bonding layer may be two separate steps. The bonding layer 101 may not be formed before the frequency adjustment layer 1010 is formed. The material of the bonding layer 101 may include silicon oxide, silicon nitride, silicon oxynitride, silicon carbonitride or ethyl silicate. In some embodiments, the material of the frequency adjustment layer 1010 and the material of the bonding layer 101 may be the same as ethyl silicate. The method of forming the bonding layer 101 and the frequency adjustment layer 1010 may include physical vapor deposition or chemical vapor deposition. For the function of the frequency adjustment layer 1010, reference can be made to the previous description, which will not be repeated here.

Referring to FIG. 14. SO5: bonding the carrier substrate 100 on the bonding layer 101, the carrier substrate 100 covering the first cavity 110a. For the material of the carrier substrate 100, reference can be made to the material of the temporary substrate 300. The carrier substrate 100 and the support layer 102 may be bonded through the bonding layer 101.

Referring to FIG. 15. SO6: removing the temporary substrate.

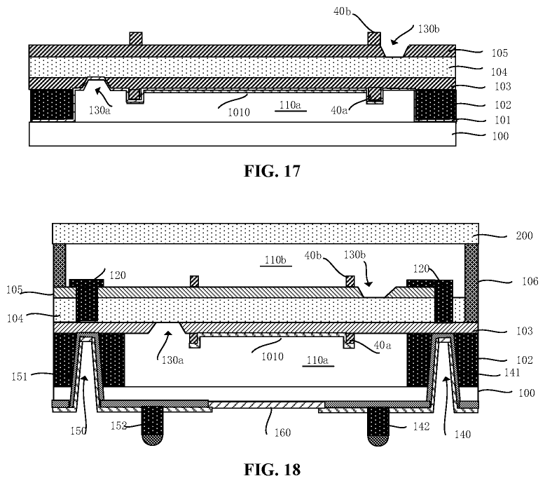

Referring to FIG. 16. SO7: forming the second bump 40b on the second electrode, the projection of the first bump 40a and/or the projection of the second bump 40b on the plane where the piezoelectric layer 104 is located including a ring shape, the ring shape including an unclosed ring or a closed ring. Referring to FIG. 17, after the process at SO7, a second trench 130b is formed on the second electrode 105 on the opposite side of the first trench 130a, the second trench 130b surrounding the second bump 40b, and the second trench 130b penetrating the second electrode 105. In this embodiment, the projections of the first trench 130a and the second trench 130b on the carrier substrate 100 meet at the two junctions of the projections. The ring shape may be a closed irregular polygon. For the structure for forming method of the second trench 130b, reference can be made to the structure and forming method of the first trench 130a. In other embodiments, only the first trench 130a or the second trench 130b may be formed alone. For the structures and functions of the first trench 130a and the second trench 130b, reference can be made to the description in previous embodiment, which will not be repeated here.

Referring to FIG. 18. In this embodiment, after the process at SO7, the method further includes forming a joining layer 106 on the piezoelectric stacked-layer structure, the joining layer 106 enclosing the second cavity 110b, the second cavity 110b being located above the first cavity 110a, and the second bump 40b being located inside the second cavity 110b; and bonding a cap substrate 200 on the joining layer 106, the cap substrate 200 covering the second cavity 110b. The method may further include forming a first electrical connection and a second electrical connection. The first electrical connection may be used for electrical connection with the first electrode of the effective resonance region, and the second electrical connection may be used for electrical connection with the second electrode of the effective resonance region. The method may further include forming a conductive interconnect structure 120 connected to the first electrode 103 and the second electrode 105 outside the effective resonance region.

In some embodiments, forming the first electrical connection may include forming a first via 140 penetrating the underlying structure of the first electrode 103 by an etching process, the first via 140 exposing the first electrode 103; forming a first conductive interconnect layer 141 in the first via 140 by an electroplating process or a physical vapor deposition process, the first conductive interconnect layer 141 covering the inner surface of the first via 140 and part of the surface of the carrier substrate 100 around the first via 140, the first conductive interconnect layer 141 being connected to the first electrode 103; forming an insulation layer 160 on the surface of the first conductive interconnect layer 141 by a deposition process; and forming a first conductive bump 142 on the surface of the carrier substrate 100, the first conductive bump 142 being electrically connected to the first conductive interconnect layer 141.

In some embodiments, forming the second electrical connection may include forming a second via 150 penetrating the underlying structure of the first electrode 103 by an etching process, the second via 141 exposing the first electrode 103; forming a second conductive interconnect layer 151 in the second via 150 by an electroplating process or a physical vapor deposition process, the second conductive interconnect layer 151 covering the inner surface of the second via 150 and part of the surface of the carrier substrate 100 around the second via 150, the second conductive interconnect layer 151 being connected to the first electrode 103; forming an insulation layer 160 on the surface of the second conductive interconnect layer 151 by a deposition process; and forming a second conductive bump 152 on the surface of the carrier substrate 100, the second conductive bump 152 being electrically connected to the second conductive interconnect layer 151.

The structure of the first electrical connection and the second electrical connection are the same, but the positions are different. Therefore, the first electrical connection and the second electrical connection may be formed at the same time, thereby saving process steps and shortening the manufacturing cycle.

In some embodiments, the conductive interconnect structure 120 may include two parts. For the positions of the two parts of the conductive interconnect structure, reference can be made to the description in the previous embodiment. The forming method of the two parts of the conductive interconnect structure may be the same. The forming method may include forming a through hole outside the effective resonance region through an etching process, the through hole penetrating the second electrode 105 and the piezoelectric layer 104 and exposing the first electrode 103; and forming the conductive interconnect structure 120 in the through hole by an electroplating process. In some embodiments, the material of the conductive interconnect structure 120 may be the same as the material of the first conductive interconnect layer 141 and the second conductive interconnect layer 151, and both may be copper. For the functions of the conductive interconnect structure 120, reference can be made to the description in the previous embodiment one.

For the materials of the cap substrate 200 and the joining layer 106, reference can be made to the description in the previous embodiment.

The fabrication method of the resonator of the present disclosure is a double-sided fabrication process, and the first bump can be formed on one side of the piezoelectric stacked-layer structure before bonding the carrier substrate. After removing the temporary substrate, the second bump can be formed on the other side of the piezoelectric stacked-layer structure. The conventional fabrication process is a single-sided fabrication process, and the bumps can only be formed on one side of the piezoelectric stacked-layer structure.

It should be noted that each embodiment in present specification may be described in a related manner, and the same or similar parts between the various embodiments may be referred to each other. Each embodiment may focus on the differences from other embodiments. Particularly, as for the method embodiments, since it is basically similar to the structure embodiments, the description thereof may be relatively simple, and reference can be made to the description of the structure embodiments. The film bulk acoustic resonator and its fabrication method consistent with the disclosure can improve the low quality factor and low structural strength caused by transverse wave leakage of the film bulk acoustic resonator.

The description presented above is merely that of a few preferred embodiments of the present invention without limiting the scope thereof in any sense. Any and all changes and modifications made by those of ordinary skill in the art based on the above teachings fall within the scope as defined in the appended claims.

What is claimed is:

1. A film bulk acoustic resonator comprising:
a carrier substrate;
a support layer bonded to the carrier substrate, the support layer enclosing a cavity, and the cavity exposing a portion of the carrier substrate;
a piezoelectric stacked-layer structure located above the support layer to cover the cavity, the piezoelectric stacked-layer structure including a first electrode, a piezoelectric layer, and a second electrode stacked in sequence from bottom to top, a region where the first electrode, the piezoelectric layer, and the second electrode above the cavity overlap each other in a direction perpendicular to a surface of the piezoelectric layer constituting an effective resonance region of the resonator; and
a first bump and a second bump disposed at a boundary of the effective resonance region, the first bump being disposed at a side where the first electrode is located, the second bump being disposed at a side where the second electrode is located, at least one of a projection of the first bump or a projection of the second bump on a plane where the piezoelectric layer is located including a ring shape, and the ring shape including an unclosed ring or a closed ring.

2. The film bulk acoustic resonator of claim 1, wherein:
the projection of the first bump and the projection of the second bump on the plane where the piezoelectric layer is located at least partially overlap with each other; or
one of the projection of the first bump and the projection of the second bump surrounds an outer periphery of another one of the projection of the first bump and the projection of the second bump.

3. The film bulk acoustic resonator of claim 1, wherein:
a material of the first bump or the second bump includes a dielectric material or a conductive material.

4. The film bulk acoustic resonator of claim 1, wherein:
the first electrode includes the first bump; and/or
the second electrode includes the second bump.

5. The film bulk acoustic resonator of claim 1, further comprising:
a trench disposed in the cavity, the trench penetrating the first electrode and surrounding an outer periphery of an area where the first bump is located.

6. The film bulk acoustic resonator of claim 5,
wherein the trench is a first trench;
the film bulk acoustic resonator further comprising:
a second trench disposed opposite to the first trench laterally, the second trench penetrating the second electrode and surrounding an outer periphery of an area where the first bump is located;
wherein a projection of the first trench and a projection of the second trench on the carrier substrate meet or have a gap at two junctions of the projection of the first trench and the projection of the second trench.

7. The film bulk acoustic resonator of claim 6, wherein:
an inner edge of the first trench coincides with an outer boundary of the first bump; and/or
an inner edge of the second trench coincides with an outer boundary of the second bump.

8. The film bulk acoustic resonator of claim 6,
wherein the cavity is a first cavity;
the film bulk acoustic resonator further comprising:
a joining layer disposed above the piezoelectric stacked-layer structure, the joining layer enclosing a second cavity exposing a portion of a surface of the piezoelectric stacked-layer structure, the second cavity being located above the first cavity, and the first trench and the second trench being located inside an area enclosed by the second cavity; and
a cap substrate disposed at the joining layer and covering the second cavity.

9. The film bulk acoustic resonator of claim 1, wherein:
a material of the support layer includes silicon oxide, silicon nitride, silicon oxynitride, silicon carbonitride, or ethyl silicate.

10. The film bulk acoustic resonator of claim 1, further comprising:
a bonding layer disposed between the support layer and the carrier substrate.

11. A film bulk acoustic resonator fabrication method comprising:
providing a temporary substrate;
forming a piezoelectric stacked-layer structure and a first bump on the temporary substrate, the piezoelectric stacked-layer structure including a second electrode, a piezoelectric layer, and a first electrode sequentially formed on the temporary substrate, the first bump being disposed at a side where the first electrode is located;
forming a support layer to cover the piezoelectric stacked-layer structure;
patterning the support layer to form a cavity, the cavity penetrating the support layer, and the first bump being located in an area enclosed by the cavity;
bonding a carrier substrate on the support layer, the carrier substrate covering the cavity;
removing the temporary substrate; and
forming a second bump on the second electrode, at least one of a projection of the first bump or a projection of the second bump on a plane where the piezoelectric layer is located including a ring shape, and the ring shape including an unclosed ring or a closed ring.

12. The film bulk acoustic resonator fabrication method of claim 11, wherein:
the projection of the first bump and the projection of the second bump on the plane where the piezoelectric layer is located at least partially overlap with each other; or
one of the projection of the first bump and the projection of the second bump surrounds an outer periphery of another one of the projection of the first bump and the projection of the second bump.

13. The film bulk acoustic resonator fabrication method of claim 12, wherein forming the first bump includes:
forming the first bump by a first method including:
forming a structural material on the temporary substrate, the second electrode, or the piezoelectric layer; and
etching the structural material layer to form the first bump;
wherein a portion of the structural material layer formed on the temporary substrate is used to form the second electrode, a portion of the structural material layer formed on the second electrode is used to form the piezoelectric layer, and a portion of the structural material layer formed on the piezoelectric layer is used to form the first electrode; or
forming the first bump by a second method including:
forming a bump material layer on the temporary substrate, the second electrode, or the piezoelectric layer or the first electrode; and
etching the bump material layer to form the first bump.

14. The film bulk acoustic resonator fabrication method of claim 12, wherein forming the second bump includes:
forming the second bump by a first method including:
forming a structural material layer on the temporary substrate; and
etching the structural material layer to form the second bump after the temporary substrate is removed;
wherein a portion of the structural material layer is used to form the second electrode; or
forming the second bump by a second method including:
forming a bump material layer on the second electrode after the temporary substrate is removed; and
etching the bump material layer to form the second bump.

15. The film bulk acoustic resonator fabrication method of claim 12, wherein forming the piezoelectric stacked-layer structure and the first bump includes:
forming the piezoelectric stacked-layer structure and the first bump by a first method including:
sequentially forming the second electrode, the piezoelectric layer, and the first electrode on the temporary substrate; and
forming the first bump on the first electrode;
forming the piezoelectric stacked-layer structure and the first bump by a second method including:
sequentially forming the second electrode and the piezoelectric layer on the temporary substrate;
forming the first bump on the piezoelectric layer; and
forming the first electrode on the first bump and the piezoelectric layer;
forming the piezoelectric stacked-layer structure and the first bump by a third method including:
forming the second electrode on the temporary substrate;
forming the first bump on the second electrode; and
sequentially forming the piezoelectric layer and the first electrode on the first bump and the second electrode; or
forming the piezoelectric stacked-layer structure and the first bump by a fourth method including:
forming the first bump on the temporary substrate; and
sequentially forming the second electrode, the piezoelectric layer, and the first electrode on the temporary substrate and the first bump.

16. The film bulk acoustic resonator fabrication method of claim 12, wherein:
the at least one of the projection of the first bump or the projection of the second bump on the plane where the piezoelectric layer is located is the ring shape.

17. The film bulk acoustic resonator fabrication method of claim 12, wherein:
the projection of the first bump and the projection of the second bump on the plane where the piezoelectric layer is located coincide with each other; or
one of the projection of the first bump and the projection of the second bump surrounds an outer periphery of another one of the projection of the first bump and the projection of the second bump.

18. The film bulk acoustic resonator fabrication method of claim 12, further comprising, before bonding the carrier substrate:
forming a trench surrounding the first bump at a bottom of the cavity and a periphery of the first bump, the trench penetrating the first electrode.

19. The film bulk acoustic resonator fabrication method of claim 18,
wherein the trench is a first trench;
the method further comprising, after forming the second bump on the second electrode:
forming a second trench on the second electrode on a side opposite to the first trench, the second trench surrounding the second bump, and the second trench penetrating the second electrode;
wherein a projection of the first trench and a projection of the second trench on the carrier substrate meet or have a gap at two junctions of the projection of the first trench and the projection of the second trench.

20. The film bulk acoustic resonator fabrication method of claim 12, wherein bonding the carrier substrate on the support layer includes:
forming a bonding layer on the support layer, the support layer and the carrier substrate being bonded through the bonding layer, and a material of the support layer and a material of the bonding layer being same.
